(19) United States
(12) Patent Application Publication
(10) Pub. No.: US 2009/0058496 A1
(43) Pub. Date: Mar. 5, 2009

(54) CIRCUIT ARRANGEMENT AND CORRESPONDING METHOD FOR CONTROLLING AND/OR PREVENTING INJECTION CURRENT

(75) Inventor: Ajay Kapoor, Eindhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/281,549

(22) PCT Filed: Feb. 13, 2007
(86) PCT No.: PCT/IB07/50468

§ 371 Date: Sep. 3, 2008

(30) Foreign Application Priority Data
Mar. 3, 2006 (EP) 06110635.7
Feb. 13, 2007 (IB) PCT/IB2007/050468

(51) Int. Cl. H03K 17/16

(52) U.S. Cl. 327/391; 327/379

(57) ABSTRACT

In order to further develop a circuit arrangement (100; 100′; 100″) as well as a corresponding method for controlling and/or for preventing injection current, said method comprising—switching at least one transistor means (20; 20′) between at least one enabled state and at least one disabled state in dependence on the signal level of at least one voltage and/or current signal, and—transmitting at least one analog and/or digital signal from at least one first pin (pin1) to at least one second pin (pin2) via at least one conductive channel (12, 14) in the enabled state of the transistor means (20; 20′), in such way that minimal disturbance due to unwanted current signals and/or due to unwanted is ensured, in particular that the MOS effect as well as the bipolar effect are prevented in the circuit arrangement (100; 100′; 100″), it is proposed—to prevent the transistor means (20; 20′) from starting to conduct due to being provided with at least one unwanted signal in its disabled state, and to prevent transmission of at least one unwanted current peak from at least one first part (12) of the conductive channel to at least one second part (14) of the conductive channel, with the transistor means (20; 20′) being arranged between said first part (12) and said second part (14).

### FIELD OF THE INVENTION

The present invention relates to a circuit arrangement, comprising
at least one conductive channel being designed for transmitting at least one analog and/or digital signal from at least one first pin to at least one second pin and
at least one transistor means
being connected between the first pin and the second pin via the conductive channel and
being switchable between at least one enabled state and at least one disabled state in dependence on the signal level of at least one voltage and/or current signal.

The present invention further relates to a corresponding method for controlling and/or for preventing injection current according to the preamble of claim 6.

### BACKGROUND OF THE INVENTION

Transistor means, such as analog switches, mu[ltiple]x[ers] and/or demu[ltiple]x[ers], are used in a variety of applications, such as in A[nalog]/D[igital] converters, in bus interfaces (as used in the telecom industry), in data acquisition systems, in level shifters, in personal computers, etc.

Conventionally, the operating voltage on I[nput]/O[utput] terminals, in particular of analog data, of the transistor means is limited to rail values wherein these rail values can vary from ground level gnd to supply voltage Vcc. However, in many applications, like automotive applications, signals with an amplitude lower than ground level gnd or higher than supply voltage Vcc frequently occur on terminals of the transistor means during disabled state or disabled mode. Such occurrence can be due to transient behavior of the circuit arrangement, to different power supplies of different parts of this circuit arrangement or to any unwanted voltage spikes etc.

The net result of this behavior is the current being sourced or sinked from the transistor means terminal being connected to this faulty line, i.e. being connected to the conductive channel provided with at least one overvoltage signal or with at least one undervoltage signal.

For analog operation, it is desirable to have minimal disturbance on the terminal of the transistor means which is not connected to the faulty line. However, in conventional analog designs, this overvoltage signal or undervoltage signal or this injection of undesired current can leak to the other side of the transistor means via two mechanisms:
signal transfer between I[nput]/O[utput] lines in the disabled state because of conduction in the transistor means via a metal-oxide semiconductor (MOS) switch, with the transistor means being disabled via internal signals in the range between ground level gnd to supply voltage Vcc; and/or
leakage between I[nput]/O[utput] lines due to parasitic bipolar effect formed between the source-bulk-drain of the MOS switch.

Consequently, signal lines or conductive channels are restricted to the power supply Vcc of the circuit arrangement, in particular of the analog switch or of the analog multiplexer and/or of the analog demultiplexer. Another way of handling such phenomena is that a system in which the circuit arrangement is used should have a power supply range equal to the voltage range of the analog signal and/or of the digital signal to be transmitted.

This causes serious hindrance in those applications where the available power supply voltage is less than the peak value of the analog signal and/or of the digital signal. In such cases, a conventional analog switch or a conventional analog multiplexer or a conventional analog demultiplexer requires a supply voltage Vcc higher than the supply voltage of subsystems to handle high voltage analog signals.

In the following, the basic introduction for the design of the transistor means, namely of a complementary metal-oxide semiconductor (CMOS), in particular of an analog switch or of an analog multiplexer or of an analog demultiplexer, is discussed.

In FIG. 1, the concept of an analog CMOS switch 20 is depicted. Said analog CMOS switch 20 comprises
a P[-channel]M[etal-]O[xide]S[emiconductor] transistor MP and
an N[-channel]M[etal-]o[xide]S[emiconductor] transistor MN.

In this scenario, the voltages on the conductive channel comprising an input line 12 and an output line 14 are in the voltage range from zero (=ground level gnd) to supply voltage Vcc.

Analog MOS switches, in particular analog CMOS switches, are used to transmit analog or digital signals across the input line 12 of the CMOS switch 20 and across the output line 14 of the CMOS switch 20 with minimal distortion, when enabled. An ideal switch acts as an open switch in the disabled state and as a short switch in the enabled state. However, in conventional MOS transistors, in particular in conventional CMOS switches, several problems occur.

An analog transistor means, in particular an analog MOS transistor, such as an analog CMOS switch, blocks signals in the disabled state of the transistor means and transmits signals in the enabled state of the transistor means. However, the transistor means can block and transmit only signals in the power supply range, i.e. in the voltage range between zero (=ground level gnd) and supply voltage Vcc.

As explained above, due to various disturbances in a system, the conductive channels, in particular the switch lines, are subject to unpredictable currents and/or to unpredictable overvoltages and/or to unpredictable undervoltages, in particular in the disabled state operation of the transistor means.

For normal operation of the overall system, the transistor means must block these unwanted signals so as to have minimal disturbance in the overall system. Otherwise, these disturbances can cause an undesired behavior in the system due to unwanted leakages between conductive channels, in particular between the switch lines.

In this context, there are mainly two mechanisms for this undesired behavior:
metal-oxide semiconductor (MOS) effect, in particular complementary metal-oxide semiconductor (CMOS) effect, and
parasitic bipolar effect.

These two mechanisms can cause problems for overvoltage signals, i.e. for signals higher than the supply voltage Vcc of the circuit arrangement. The same mechanisms hold for undervoltage signals, i.e. for signals lower than ground level gnd as well:

In FIG. 2, the MOS effect, in particular the CMOS effect, is depicted. A PMOS transistor MP starts conducting if the voltage on its drain/source is more than the voltage on its gate MPg. In FIG. 2, a first part 12 of the conductive channel is provided with a voltage higher than the supply voltage Vcc, and a second part 14 of the conductive channel is provided with a voltage lower than the voltage of the first line 12.

In the disabled state operation of the switch, the PMOS is disabled by providing at least one signal equal to the supply voltage Vcc on the gate MPg of the PMOS. So, if there is an unwanted current at the drain of the PMOS or at the source of the PMOS, the voltage on the drain of the PMOS or on the source of the PMOS tends to rise above the supply voltage Vcc. This causes a current path CP from the drain side to the source side or vice versa due to the PMOS being partially turned-on being or fully turned-on.

The CMOS effect, i.e.
the PMOS conduction in overvoltage conditions in the disabled state of the PMOS and/or
the NMOS conduction in undervoltage conditions in the disabled state of the NMOS,
   should be suppressed.

In FIG. 3, the bipolar effect is depicted. A weak parasitic bipolar transistor (PNP transistor) is formed by the source-drain-backgate, in particular by the emitter-collector-base, of the PMOS. Though this is a very weak bipolar with very low current gain (h_{fe}) but still it transmits finite signals from one side to the other side, when active. Also, in normal simulations this kind of leakage is hardly modeled. Thus, an extra precaution is required to suppress this effect.

FIG. 3 depicts parasitic PNP-bipolar conduction in overvoltage conditions. The first part 12 of the conductive channel is provided with a voltage higher than the supply voltage Vcc, and the second part 14 of the conductive channel is provided with a voltage lower than the voltage of the first line 12.

Circuits for preventing the parasitic bipolar effect in analog switches or in analog multiplexers or in analog demultiplexers are respectively described
in product information sheet “SN74HC4851, 8-channel analog multiplexer/demultiplexer with injection-current effect control” by Texas Instruments Incorporated, SCLS542B, September 2003, revised January 2004, cf. http://focus.ti.com/lit/ds/symlink/sn74hc4851.pdf,
in product information sheet “SN74HC4851 Analog multiplexer/demultiplexer with injection current effect control” by Texas Instruments Incorporated, SCYB019A, 2004, cf. http://focus.ti.com/pdfs/logic/hc4851prodclip1.pdf,
in product information sheet “MC74HC4851A, MC74HC4852A Analog Multiplexers/Demultiplexers with Injection Current Effect Control” by Semiconductor Components Industries LLC, MC74HC4851A/D, revision 6, June 2005, cf. http://www.onsemi.com/pub/Collateral/mc74hc4851a-d.pdf,
in prior art document EP 0 729 232 A1 where an analog switch having shunt transistors functioning to block the flow of injection currents associated with the switching transistors is provided,
in prior art document EP 1 199 801 A1 where a circuit for current injection control in analog switches prevents the parasitic bipolar effect of the MOSFET transistors composing the analog switch from turning on, and
in prior art document U.S. Pat. No. 5,994,744.

The circuits described in these prior art documents only take care of the parasitic bipolar effect; the MOS effect is not dealt with in these prior art documents. Therefore, these analog switches and multiplexers/demultiplexers can work only if it is ensured that the MOS will not become active, which is possible only when a very effective sink is used, for example when low threshold diodes are used, which is a very costly process, or when the size of the additional circuitry is enormously increased.

Another solution can be to use T-switch construction to block excessive currents. However, the use of a T-switch like construction leads to the disadvantages that
that the switch or multiplexer/demultiplexer requires a large silicon area, which makes the switch or multiplexer/demultiplexer too costly to be mass produced and to compete, and
that the on-resistance of the switch or multiplexer/demultiplexer at low voltages increases enormously.

With respect to the MOS effect, prior art document GB 2 319 128 A discloses a CMOS transmission gate multiplexer with improved off-isolation; a transmission cell for transmitting a signal from an input to an output in response to a control signal is provided.

Moreover, in prior art document U.S. Pat. No. 6,567,024 B1 an analog switch is disclosed comprising means for restraining injection current. This conventional analog switch comprises a pair of transfer gates with a pair of transistors whose conduction is enabled and disabled by control signals. The back gate, the source and the drain of one of these transistors are coupled to input and output ends.

However, the parasitic bipolar effect is dealt with neither in prior art document GB 2 319 128 A nor in prior art document U.S. Pat. No. 6,567,024 B1.

### OBJECT AND SUMMARY OF THE INVENTION

Starting from the disadvantages and shortcomings as described above and taking the prior art as discussed into account, an object of the present invention is to further develop a circuit arrangement of the kind as described in the technical field as well as a method of the kind as described in the technical field in such way that minimal disturbance due to unwanted current signals and/or due to unwanted voltage signals on the conductive channel is ensured, in particular that the MOS effect as well as the bipolar effect are prevented in the circuit arrangement; such unwanted signals can be
at least one overvoltage signal and/or at least one undervoltage signal from a voltage source or
finite current sourced or sinked from at least one current source connected to the conductive channel.

The object of the present invention is achieved by a circuit arrangement comprising the features of claim 1 as well as by a method comprising the features of claim 6. Advantageous embodiments and expedient improvements of the present invention are disclosed in the respective dependent claims.

The present invention is based on the idea of providing a circuit arrangement, in particular a M[etal-]O[xide]S[emiconductor] analog switch or a MOS analog multiplexer and/or a MOS analog demultiplexer, the circuit arrangement having at least one injection current effect control, wherein said injection current effect control is in particular based
on blocking overvoltages and/or on blocking undervoltages, and
on at least one source-sink and/or
on at least one bipolar effect prevention.

Thus, the present invention proposes a circuit arrangement, in particular an analog switch scheme, which can handle the unwanted signal, in particular
at least one signal higher than the supply voltage range and/or lower than grounding level and/or
at least one current peak,
   on the first part of the conductive channel as well as on the second part of the conductive channel in the disabled state of the transistor means without disturbing the other part of the conductive channel and vice versa.

The transistor means can be implemented as at least one metal-oxide semiconductor (MOS), in particularly as at least one complementary metal-oxide semiconductor (CMOS), for example as at least one complementary high-density metal-oxide semiconductor (CHMOS) and/or as at least one bipolar complementary metal-oxide semiconductor (BiCMOS).

Thus, according to a preferred embodiment of the present invention the transistor means comprises at least one p-type transistor unit, in particular at least one p-channel metal-oxide semiconductor (PMOS) or p-type metal-oxide semiconductor field effect transistor (PMOSFET), starting to conduct in case of at least one negative voltage being placed on its gate electrode.

Moreover, the transistor means advantageously comprises at least one n-type transistor unit, in particular at least one n-channel metal-oxide semiconductor (NMOS) or n-type metal-oxide semiconductor field effect transistor (NMOSFET), starting to conduct in case of at least one positive voltage being placed on its gate electrode.

Preventing the transistor means from starting to conduct due to being provided with at least one unwanted signal in its disabled state can for example be implemented
as preventing the PMOS of the transistor means from starting to conduct in the disabled state of the PMOS and/or
as preventing the NMOS of the transistor means from starting to conduct in the disabled state of the NMOS,
   wherein according to a preferred embodiment of the present invention the PMOS is enabled when the NMOS is disabled, and vice versa.

The enabling and disabling of the transistor means, in particular of the PMOS and/or of the NMOS, can be performed by means of at least one enable signal and/or by means of at least one disable signal.

According to a preferred embodiment of the present invention, the unwanted signal handling capability, in particular the overvoltage handling capability and the undervoltage handling capability, is achieved by providing the state control circuit, in particular by providing
at least one unwanted signal detection, for example at least one overvoltage detection and/or at least one undervoltage detection, and
at least one signal level circuit, for example at least one leakage prevention scheme, to prevent MOS channel formation.

For preventing MOS channel formation, the signal level circuit is preferably designed for controlling the signal level of at least one electrode of the transistor means, in particular
for rising the signal level of the gate electrode of the p-type transistor unit in case of overvoltage and/or
for lowering the signal level of the gate electrode of the n-type transistor unit in case of undervoltage.

Moreover, for preventing the unwanted signal from being transmitted to at least one power supply, the state control circuit advantageously comprises at least one backflow-prevention circuit.

For achieving the unwanted signal handling capability according to a preferred embodiment of the present invention, the current control circuit is designed for ensuring at least one current sinking capability on the first part, such as on at least one analog input line, of the conductive channel, and/or on the second part, such as on at least one analog output line, of the conductive channel, to kill the leakage due to the parasitic bipolar effect.

For this reason, the current control circuit advantageously comprises
at least one first source-sink circuit
being arranged between the first pin and the transistor means and
being designed for eliminating the unwanted current peak being provided by at least one impedance source, in particular by at least one current source, being connected to the first part of the conductive channel, and
at least one second source-sink circuit
being arranged between the transistor means and the second pin and
being designed for eliminating the unwanted current peak being provided by at least one impedance source, in particular by at least one current source, being connected to the second part of the conductive channel.

Thus, the current control circuit is advantageously designed as at least one built-in current-source/current-sink capability, which allows overvoltage and undervoltage, for example in excess of supply rail, on each side of the transistor means without disturbing the other side of the transistor means in the disabled state.

Moreover, for protecting the transistor means against at least one parasitic bipolar effect, in particular for preventing the transistor means from signal leakage due to said parasitic bipolar effect, the circuit arrangement preferably comprises at least one bipolar control circuit.

For preventing at least one current from being injected into at least one backgate of the transistor means, in particular from being injected into at least one parasitic bipolar transistor being formed by at least one source-drain-backgate of the transistor means, for example by at least one emitter-collector-base of the transistor means, the bipolar control circuit advantageously comprises at least one backflow-prevention circuit.

For controlling, in particular for dynamically controlling, the voltage level of the backgate of the transistor means, in particular for rising and/or for lowering the voltage level of said backgate of the transistor means, in dependence on the voltage level of the first pin and/or of the second pin and/or of the power supply, the bipolar control circuit preferably comprises at least one backgate control circuit.

Independently thereof or in combination therewith the circuit arrangement is preferably fully static, which makes it usable in advanced low power applications.

According to a preferred embodiment of the present invention the circuit arrangement is implemented as a low voltage analog switch structure, preferably being in compliance with conventional industrial switches, for example with the 4066 switch (cf. http://www.standardics.philips.com/products/hc/pdf/74hc_hct4066.pdf).

Moreover, the circuit arrangement according to the present invention can be implemented as at least one analog multiplexer (Mux) and/or as at least one analog demultiplier (DeMux).

According to a preferred embodiment of the present invention the circuit arrangement comprises the injection-current effect control as described above and is implemented for example in an N-well with 0.35 micrometer complementary metal-oxide semiconductor (CMOS) process with operating voltage of about 1.65 Volt to about 3.6 Volt. However, the present invention can also be used in P-well processes or in BiCMOS processes.

The circuit arrangement according to the present invention is advantageously used for applications such as automotive, where voltages in excess of normal supply voltages are common.

In the enabled state, the circuit arrangement, in particular the transistor means, can transfer the analog and/or digital signal in the range of ground level (vanishing voltage) to supply voltage across its conductive channel.

In the disabled state, the circuit arrangement, in particular the transistor means, blocks the transmitting of the analog and/or digital signal across its conductive channel.

The present invention leads to the advantage that current-injection effect control can be realized.

Moreover, the problem or disadvantage of rail-to-rail voltage limitations of a conventional CMOS switch can be overcome in a static way by the present invention.

Further benefits of a preferred embodiment of the present invention are:
injection current protection for use in harsh environments, such as automotive environments;
injection current cross coupling being less than 10⁻³ Volt/10⁻³ Ampere;
low crosstalk between a plurality of circuit arrangements being connected together;
extended temperature range from −40 degree Celsius to 125 degree Celsius; and
pin compatible with conventional multiplexer/demultiplexer devices.

The circuit arrangement according to the present invention is preferably qualified in accordance with the stress test qualification AEC-Q100 (Q1) for integrated circuits of A[utomotive]E[lectronics]C[ouncil].

A first level analysis indicates that a preferred embodiment of the circuit arrangement according to the present invention is four times smaller in terms of area than conventional circuit arrangements comprising a circuit for preventing the parasitic bipolar effect. Thus, the circuit arrangement according to the present invention can be produced at cheaper cost.

Finally, the present invention relates to the use of at least one circuit arrangement as described above and/or of the method as described above
for at least one application where overvoltage, for example voltage in excess of normal supply voltage, may appear and/or
in at least one A[nalog]/D[igital] converter, in at least one bus interface, in at least one data acquisition system, in at least one level shifter, and/or in at least one personal computer.

In this context the circuit arrangement can be implemented as at least one switching device, in particular as at least one analog switch, and/or as at least one multiplexing device (Mux) and/or as at least one demultiplexing device (DeMux), for example as at least one analog multiplexer and/or as at least one analog demultiplexer.

### BRIEF DESCRIPTION OF THE DRAWINGS

As already discussed above, there are several options to embody as well as to improve the teaching of the present invention in an advantageous manner. To this aim, reference is made to the claims respectively dependent on claim 1 and on claim 6; further improvements, features and advantages of the present invention are explained below in more detail with reference to three preferred embodiments by way of example and to the accompanying drawings where

FIG. 1 schematically shows an embodiment of a transistor means in the form of an analogue CMOS switch;

FIG. 2 schematically illustrates the CMOS effect, in particular a PMOS conduction in overvoltage conditions in the disabled state of the transistor means of FIG. 1;

FIG. 3 schematically shows the parasitic bipolar effect, in particular a parasitic PNP-bipolar conduction in overvoltage conditions of the transistor means of FIG. 1;

FIG. 4A schematically shows a first embodiment of the circuit arrangement according to the present invention;

FIG. 4B schematically shows in more detail an embodiment of the state control circuit of the circuit arrangement of FIG. 4A;

FIG. 4C schematically shows in more detail an embodiment of the bipolar control circuit of the circuit arrangement of FIG. 4A;

FIG. 4D schematically shows in more detail an embodiment of the current control circuit of the circuit arrangement of FIG. 4A;

FIG. 5A schematically shows a second embodiment of the circuit arrangement according to the present invention in the form of an embodiment for a simulation setup of current-injection effect control according to the present invention;

FIG. 5B diagrammatically shows simulation results for the current-injection effect control of FIG. 5A;

FIG. 5C diagrammatically shows in more detail simulation results for the current-injection effect control of FIG. 5A;

FIG. 6A schematically shows a third embodiment of the circuit arrangement according to the present invention in the form of another embodiment for a simulation setup of current-injection effect control according to the present invention in overvoltage conditions;

FIG. 6B diagrammatically shows simulation results for overvoltage leakage; and

FIG. 6C diagrammatically shows in more detail simulation results for overvoltage leakage.

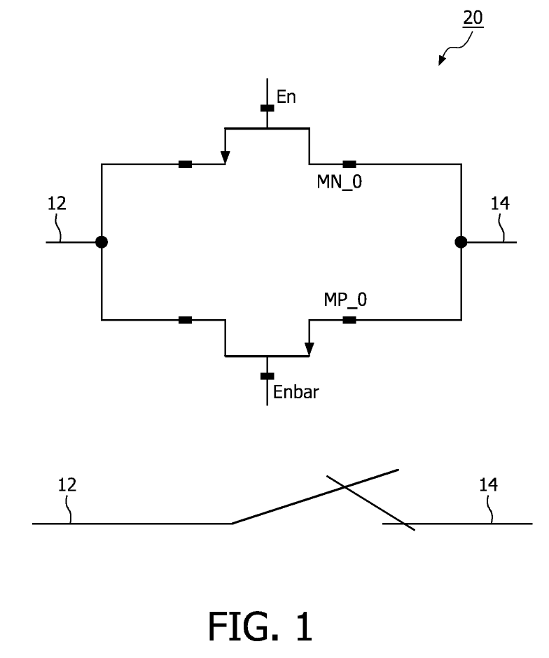

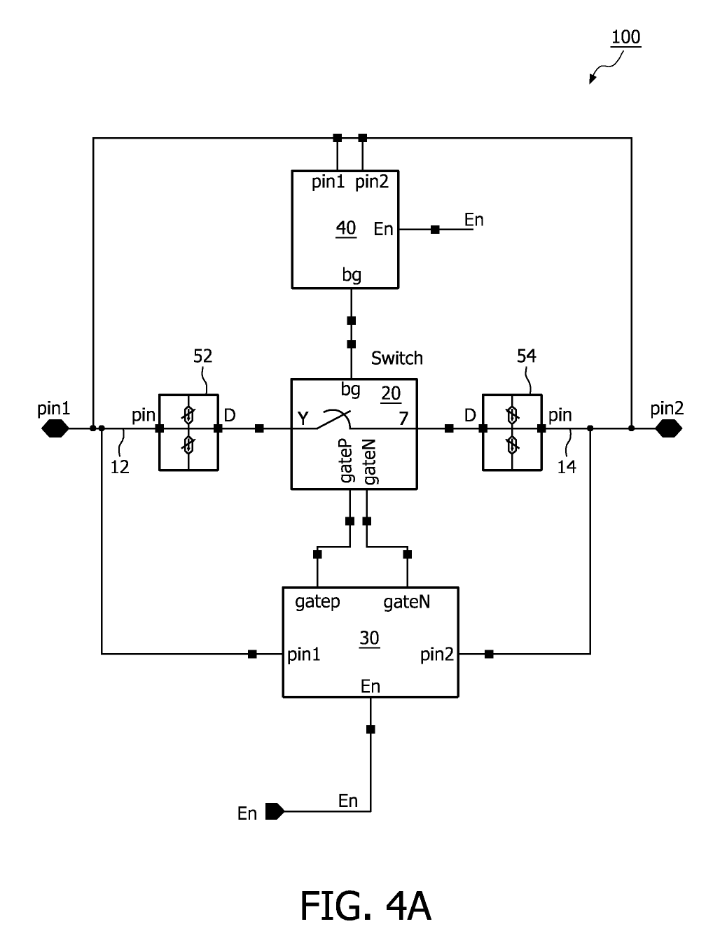

The same reference numerals are used for corresponding parts in FIG. 1 to FIG. 6C.

### DESCRIPTION OF EMBODIMENTS

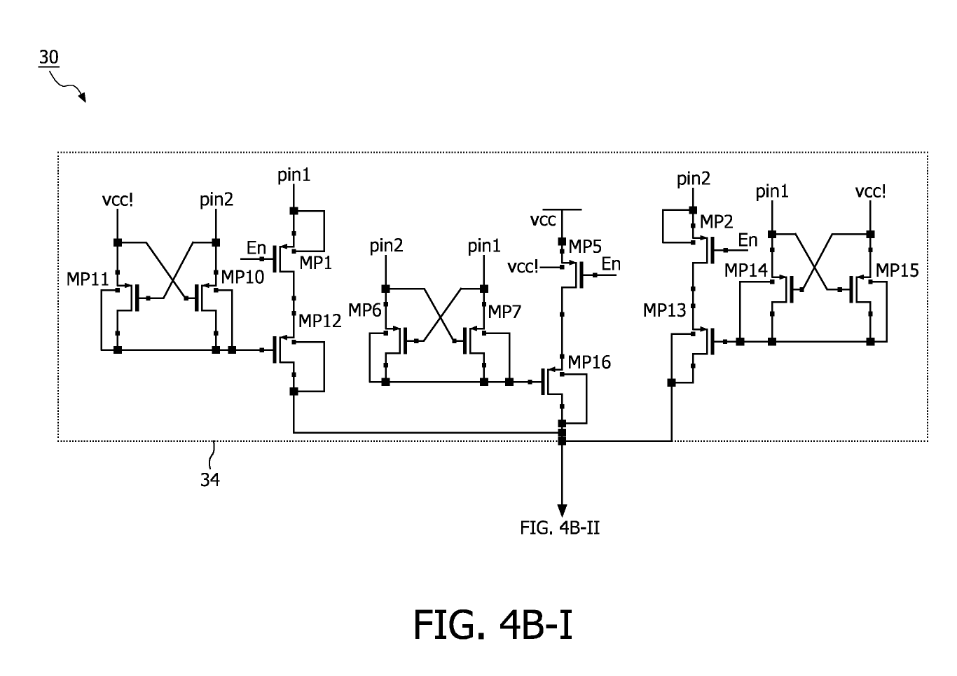

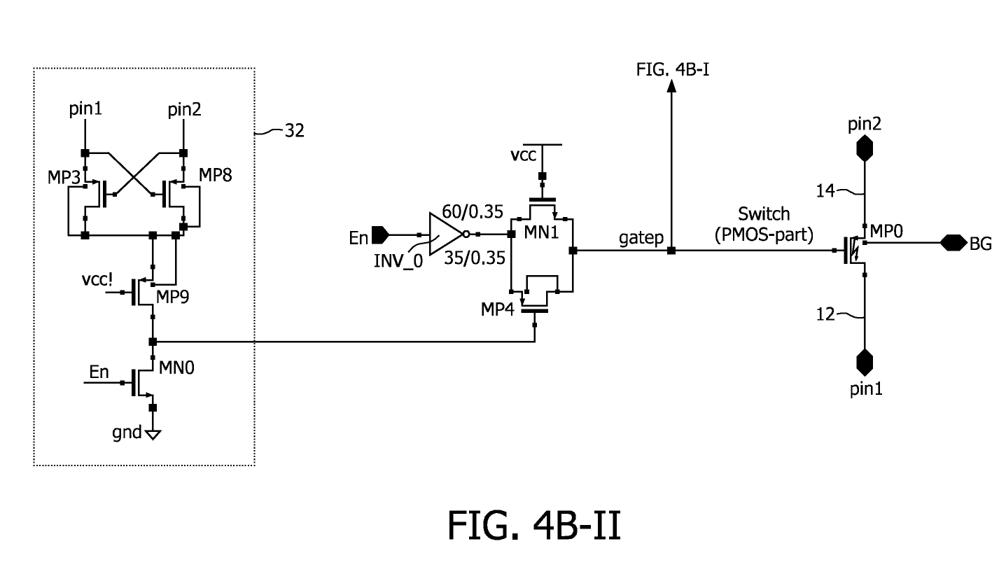

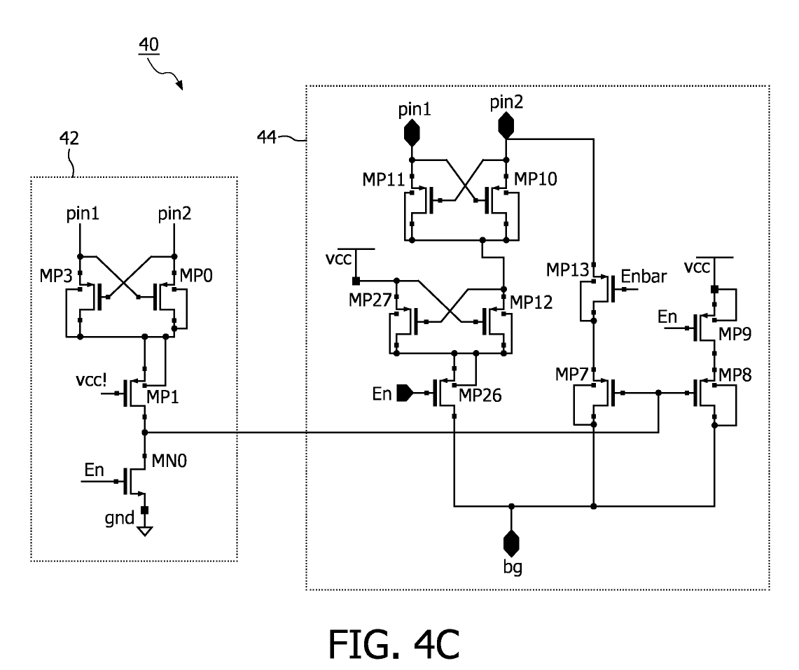

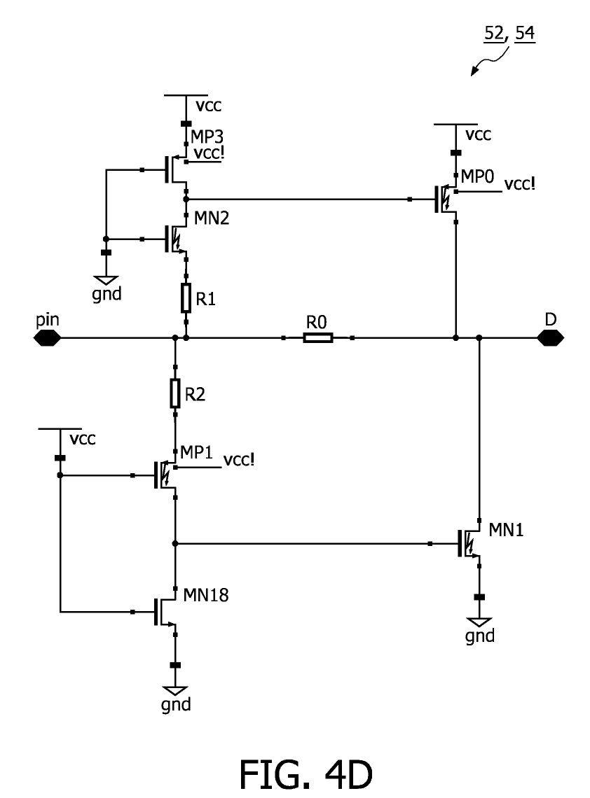

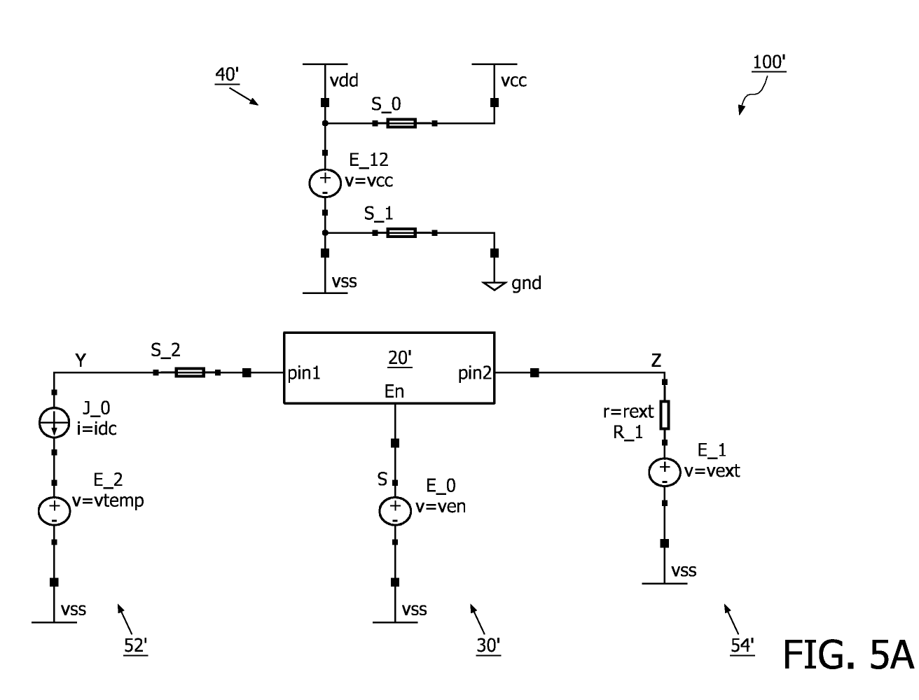

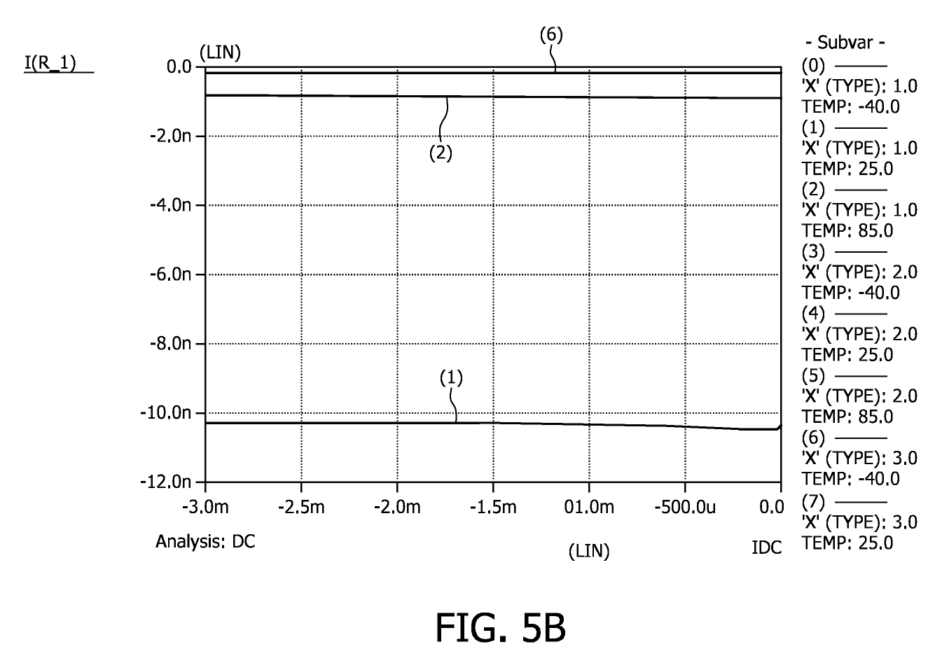

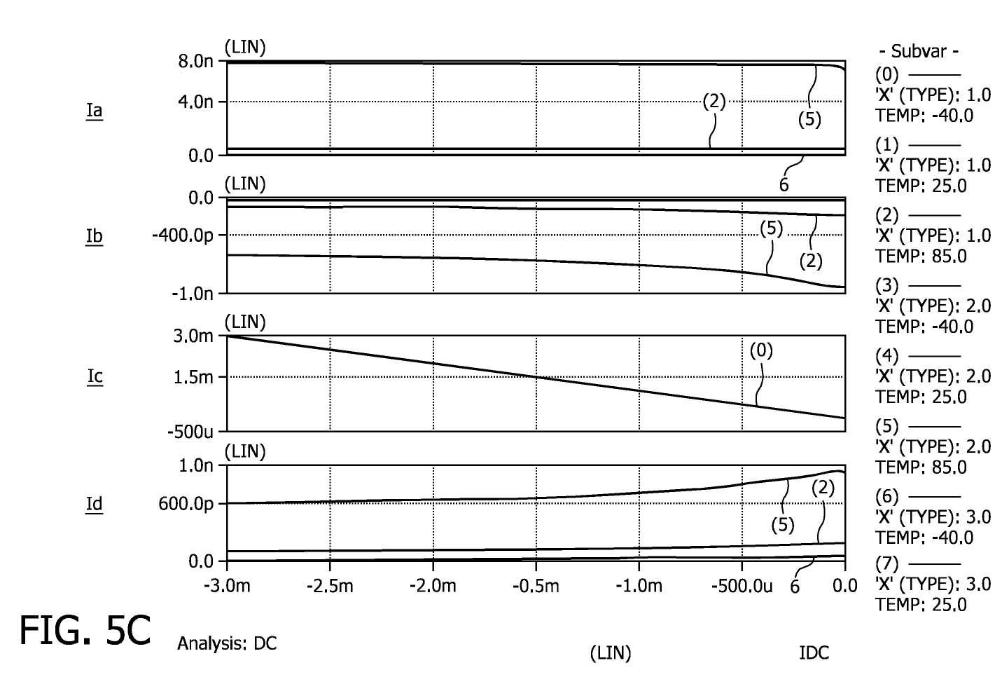

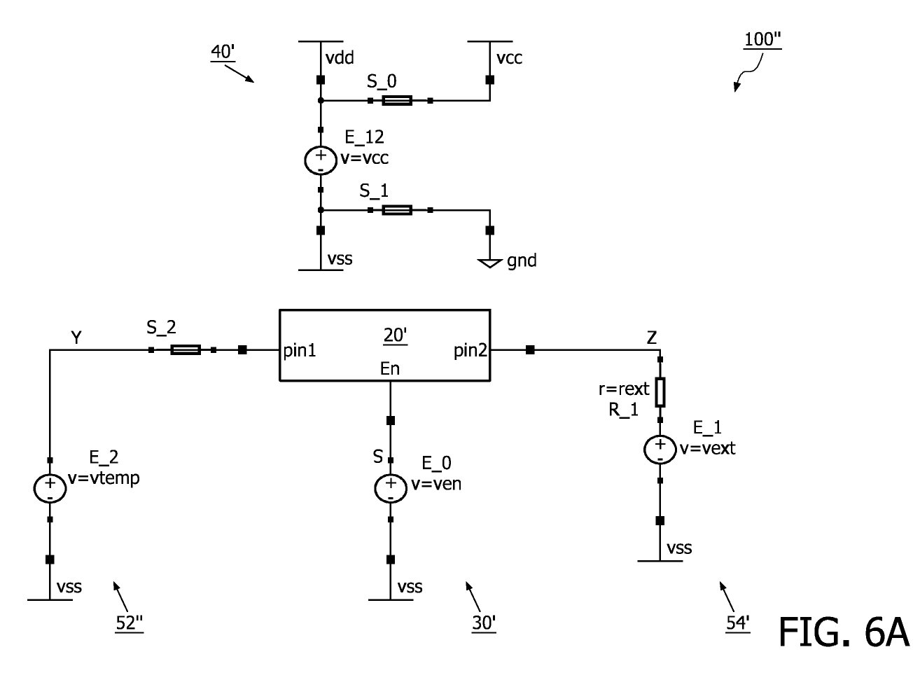

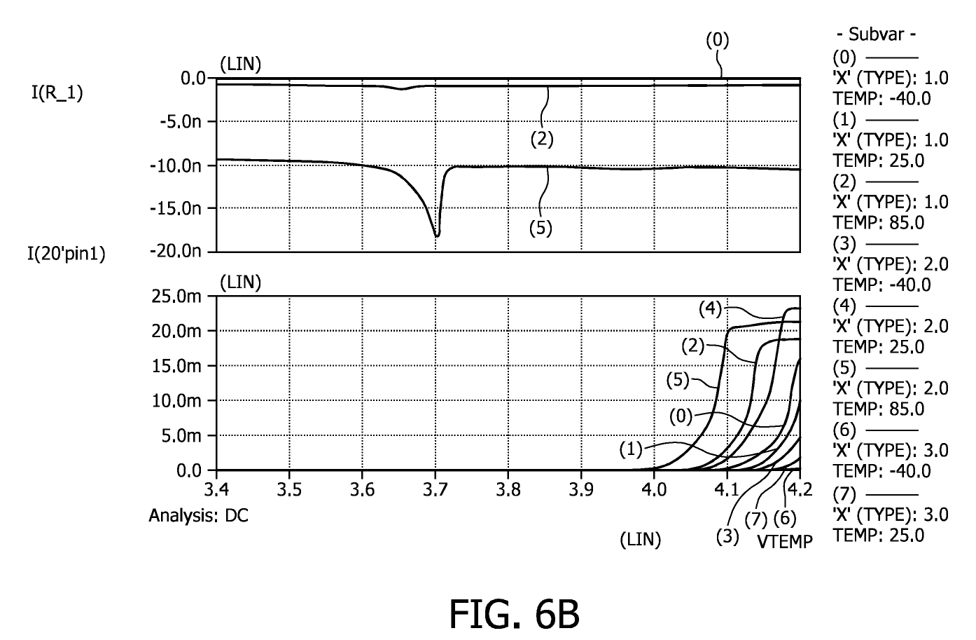

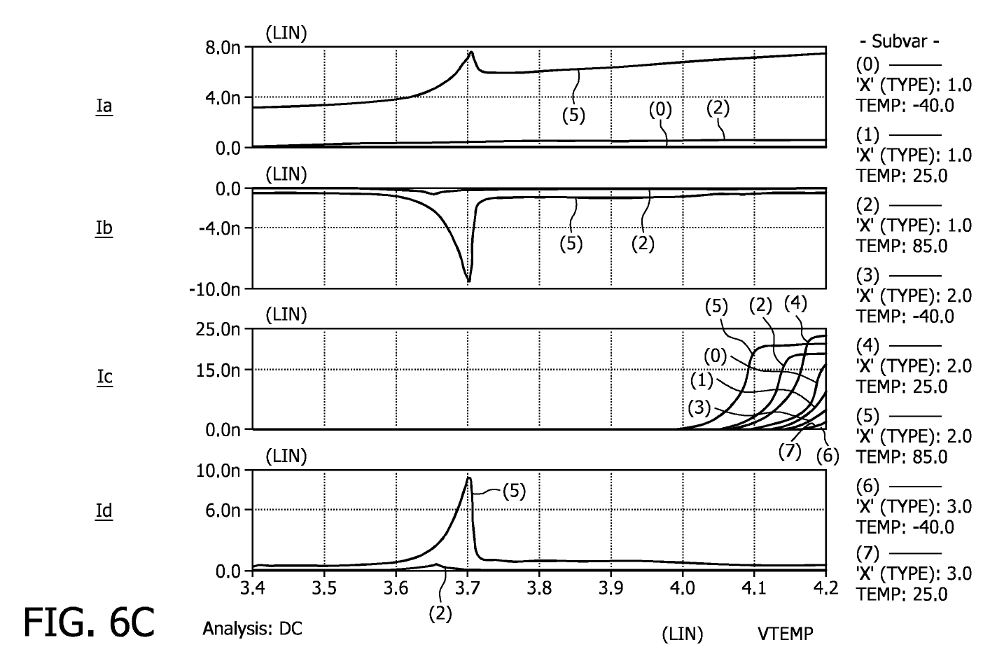

In order to avoid unnecessary repetitions, the following description regarding the embodiments, characteristics and advantages of the present invention relates (unless stated otherwise)
to the first embodiment of the circuit arrangement 100 according to the present invention (cf. FIG. 4A to FIG. 4D) as well as
to the second embodiment of the circuit arrangement 100′ according to the present invention (cf. FIG. 5A to FIG. 5C) as well as
to the third embodiment of the circuit arrangement 100″ according to the present invention (cf. FIG. 6A to FIG. 6C),
   all embodiments 100, 100′, 100″ being operated according to the method of the present invention.

In FIG. 4A, an embodiment of the circuit arrangement 100, namely of an analogue switch, according to the present invention is depicted.

This analogue switch comprises a switching unit being designed as transistor means 20, namely as a metal-oxide semiconductor (MOS), in particular as a complementary metal-oxide semiconductor (CMOS).

Said CMOS 20 comprises
at least one p-type transistor unit MP, in particular at least one p-channel metal-oxide semiconductor (PMOS) or p-type metal-oxide semiconductor field effect transistor (PMOSFET), starting to conduct in case of application of a higher voltage on its drain electrode and/or on it source electrode than on its gate electrode, and
at least one n-type transistor unit MN, in particular at least one n-channel metal-oxide semiconductor (NMOS) or n-type metal-oxide semiconductor field effect transistor (NMOSFET), starting to conduct in case of application of a lower voltage on its drain electrode and/or on it source electrode than on its gate electrode.

The CMOS 20, in particular the transistors of the CMOS 20, i.e. the PMOS transistor MP and the NMOS transistor MN, are switchable between the enabled state or enabled mode and the disabled state or disabled mode by being provided with enable signals EN. Preferably, only one of the PMOS transistor(s) MP and/or of the NMOS transistor(s) MN is enabled or switched on at any time.

In the enabled state or enabled mode, the CMOS 20, in particular the enabled transistor unit of the CMOS 20, for example the enabled PMOS or the enabled NMOS, can pass analog and/or digital signals in the range of its power supply Vcc across a first part 12 of a conductive channel, namely from an input line, to a second part 14 of the conductive channel, namely to an output line.

In the disabled state or disabled mode, the CMOS 20, in particular the disabled transistor unit of the CMOS 20, for example the disabled PMOS or the disabled NMOS, blocks the analog and/or digital signals from being transmitted from the input line 12 to the output line 14, to which aim the CMOS 20 is arranged between said input line 12 and said output line 14.

However, it has to be taken into account that in many applications, like for instance in automotive applications, the analogue switch 100 can be subjected to one or more unwanted signals, such as excessive current and/or excessive voltage, especially in the disabled state of the CMOS 20 or in the so-called off-state of the CMOS 20.

In contrast to conventional switches, the CMOS 20 of the present invention is capable of blocking such unwanted signal from being transmitted from the disturbed side of the CMOS 20, i.e. from the first part 12 or the second part 14 of the conductive channel being provided with the unwanted signal, to the undisturbed side of the CMOS 20, i.e. to the other part 14 or 12 of the conductive channel.

To ensure minimal disturbance due to the unwanted signal on the conductive channel 12, 14, the MOS effect, in particular the CMOS effect, and the bipolar effect are prevented in the circuit arrangement 100 in the disabled state of the CMOS 20, in particular in the disabled state of the PMOS and/or in the disabled state of the NMOS.

Therefor, the analogue switch 100 comprises three main circuit blocks as shown in FIG. 4A, namely
a state control circuit or dualovervoltage block 30 for preventing the MOS effect, i.e. for preventing the CMOS 20 from turning on due to being provided with one or more unwanted signals in disabled state of the CMOS 20,
a bipolar control circuit or BG_logic block 40 for preventing the turning on of the parasitic bipolar effect, and
a current control circuit comprising one source-sink block 52, 54 on each side of the CMOS 20, namely
a source-sink block 52 being assigned to the input line 12 of the conductive channel, as well as
a source-sink block 54 being assigned to the output line 14 of the conductive channel,
wherein the current control circuit is designed for supplying or sinking the unwanted current spikes from the conductive channel 12, 14.

In FIG. 4B, a schematic diagram of the state control circuit or dualovervoltage block 30 is depicted:

The dualovervoltage block 30 is designed for preventing the CMOS effect, namely for preventing leakage due to conductive channel formation between a first pin [-->reference numeral pin1], said first pin being assigned to the input line 12 of the conductive channel, and a second pin [-->reference numeral pin2], said second pin being assigned to the output line 14 of the conductive channel, in the disabled state or disabled mode of the CMOS 20, in particular in the disabled state or disabled mode of the PMOS and/or of the NMOS.

In FIG. 4B, the state control circuit or dualovervoltage block 30 is depicted for PMOS only but the complementary scheme can be equally used for NMOS.

For preventing the PMOS of the switching unit 20 from starting to conduct in the disabled state or disabled mode, after detecting the overvoltage signal the signal level of at least one electrode of the PMOS is controlled, more particularly the signal level of at least one gate electrode [-->reference numeral gatep] of the PMOS is raised.

Thus, at least one inverter [-->reference numeral Inv_0 in FIG. 4B] provides the gate [-->reference numeral gatep in FIG. 4B] of the PMOS with one or more high voltage signals in the disabled state or disabled mode of the PMOS [-->reference numeral MP0 in FIG. 4B] of the switching unit 20. The PMOS can for example be disabled by being provided with one or more low enable signals [-->reference numeral En in FIG. 4B].

Said high voltage signal for preventing the PMOS [-->reference numeral MP0 in FIG. 4B] from starting to conduct in the disabled state is advantageously transmitted via at least one further transistor unit. As depicted in FIG. 4B, the inverter [-->reference numeral Inv_0 in FIG. 4B] puts the high level (=supply voltage Vcc) at the gate [-->reference numeral gatep in FIG. 4B] of the PMOS [-->reference numeral MP0 in FIG. 4B] via the further PMOS transistor unit [-->reference numeral MP4 in FIG. 4B] and via the further NMOS transistor unit [-->reference numeral MN1 in FIG. 4B].

The state control circuit or dualovervoltage block 30 comprises
a backflow-prevention circuit 32 and
a signal level circuit in the form of a so called Max-finder circuit block 34:

When the overvoltage signal occurs on any of the lines 12, 14 of the conductive channel, the signal level circuit or Max-finder circuit block 34 Is activated and raises the signal level at the gate [-->reference numeral gatep in FIG. 4B] of the PMOS to the maximum of the first pin [-->reference numeral pin1], of the second pin [-->reference numeral pin2], and of the supply voltage [-->reference numeral Vcc].

The backflow-prevention circuit 32 prevents the flow of current from the first pin or second pin [-->reference numeral pin1 or reference numeral pin2] and/or from the conductive channel line 12, 14 being provided with the overvoltage to the power supply Vcc of the transistor means 20, wherein said backflow is prevented via the further PMOS transistor [-->reference numeral MP4 in FIG. 4B] and via the inventer [-->reference numeral Inv_0 in FIG. 4B].

In this way, the gate electrode [-->reference numeral gatep] of the PMOS of the switching unit 20 is dynamically raised to the maximum voltage level, and no conductive channel is formed between the input line 12 and the output line 14. Thus, the leakage from one side of the switching unit 20 to the other side of the switching unit 20, due to CMOS effect, is prevented.

In FIG. 4C, a schematic diagram of the bipolar control circuit or so called BG_logic circuit block 40 for preventing the parasitic bipolar effect is depicted:

The state control circuit or dualovervoltage circuit 30 depicted in FIG. 4B prevents the leakage between the input line 12 and the output line 14 due to the CMOS effect. However, in addition to the CMOS effect, there is a parasitic bipolar formed by drain-source-backgate of the PMOS (cf. chapter “Background and prior art” above).

For protecting the switching unit 20 from the parasitic bipolar effect the voltage level of a backgate [-->reference numeral bg in FIG. 4C] of the switching unit 20 is controlled, in particular the voltage level of said backgate bg is raised and/or lowered in dependence on the voltage level of the first pin [-->reference numeral pin1] and/or of the second pin [-->reference numeral pin2] and/or of the power supply voltage [-->reference numeral Vcc].

More particularly, to prevent the parasitic bipolar effect, the current injected into the base-emitter (drain-backgate) junction of this bipolar transistor is to be avoided. This is achieved by raising the backgate voltage of the PMOS-switch to the maximum of the first pin [-->reference numeral pin1], of the second pin [-->reference numeral pin2], and of the supply voltage [-->reference numeral Vcc].

In this way, there is no forward bias across the base-emitter region of the bipolar, and consequently there is no leakage between the emitter and the collector of the parasitic bipolar (drain and source of the MOS).

Moreover, as depicted in FIG. 4C, the bipolar control circuit or so called BG-logic circuit block 40 comprises a backflow-prevention circuit 42 for the current being provided due to the parasitic bipolar effect from being injected into the backgate bg of the switching unit 20, in particular from being injected into one or more parasitic bipolar transistors PNP being formed by one or more source-drain backgates of the switching unit 20.

In FIG. 4D, a schematic diagram of the current control circuit 52, 54 is depicted:

This current control circuit 52, 54 is designed for preventing that one or more unwanted current peaks are transmitted from the input line 12 of the conductive channel to the output line 14 of the conductive channel.

This current control circuit 52, 54 comprises
a first source-sink circuit 52 being arranged between the first pin [-->reference numeral pin1] and the switching unit 20, and
a second source-sink circuit 54 being arranged between the switching unit 20 and the second pin [-->reference numeral pin2].

Thus, a source-sink block 52, 54 is attached to each side of the switching unit 20.

As stated above with reference to FIG. 4B and with reference to FIG. 4C, the state control circuit or dualovervoltage block 30 and the bipolar control circuit or BG_logic block 40 are designed for preventing the analogue switch 100 from leakage due to an overvoltage signal being supplied to the conductive channel 12, 14 by means of a voltage source or by means of a low impedance source.

In contrast thereto, the current control circuit 52, 54 is designed for preventing the conductive channel 12, 14 from disturbance due to unwanted current spikes being provided by a current source or by means of a high impedance source.

To prevent these current spikes from building very high voltage on the conductive channel 12, 14 and to prevent circuits connected to the conductive channel 12, 14 from breakdown under such stress, the current control circuit 52, 54 sources or sinks the current corresponding to these spikes from the conductive channel 12, 14.

For preventing the transmission of the unwanted current peak(s), the current control circuit 52, 54 senses the unwanted current peak(s) by means of at least one sensor means, in particular by means of at least one sensing transistor unit, for example by means of at least one further PMOS [-->reference numeral MP1 in FIG. 4D].

The size of this sensing transistor unit [-->reference numeral MP1 in FIG. 4D] dictates the efficiency of the current control circuit 52, 54
for sensing the overvoltage signal being supplied to the conductive channel 12, 14 by means of a voltage source or by means of a low impedance source and/or
for sensing the current peak on the conductive channel 12, 14.

Moreover, for preventing the transmission of the unwanted current peak, the current control circuit 52, 54 provides at least one low impedance path for the current peak to the power supply Vcc and/or to the grounding gnd.

More particularly, the current control circuit 52, 54 dynamically senses the overvoltage and/or the undesired current signal on the conductive channel 12, 14 and offers the low impedance path for this current to the power supply Vcc and/or to the grounding gnd of the analog switch 100 via the PMOS transistor unit [-->reference numeral MP0 in FIG. 4D] and via the NMOS transistor unit [-->reference numeral MN1 in FIG. 4D].

In this way, the current control circuit 52, 54 maintains the voltage of the lines 12 14 of the conductive channel within tolerable limits.

In an undesired current mode, the overvoltage protection circuit blocks, i.e.
the state control circuit or so-called dualovervoltage block 30 as well as
the bipolar control circuit or so called BG_logic block 40
   advantageously ensure that even small currents build up good enough voltage on the respective line 12, 14 being supplied with the unwanted current to activate the respective source-sink circuit 52, 54 being assigned to the disturbed line.

Thereby, the dualovervoltage block 30 as well as the BG_logic block 40 reduce the requirement on the size of the sensing transistor unit [-->reference numeral MP1 in FIG. 4D].

The working of the current control circuit 52, 54 can be understood as follows: The sensing transistor unit [-->reference numeral MP1 in FIG. 4D] starts to conduct a small current as soon as voltage on at least one of the lines 12, 14 of the conductive channel goes higher than the supply voltage Vcc.

This conduction of the sensing transistor unit [-->reference numeral MP1 in FIG. 4D] causes a current i1. Said current i1 is converted into voltage V1 via resistance R1 wherein said converted voltage V1=i1*R1.

The voltage signal V1 is fed to the gate of one or more NMOS transistor units [-->reference numeral MN1 in FIG. 4D]. Thereby, the NMOS transistor [-->reference numeral MN1 in FIG. 4D] is turned on in proportion to the disturbance of the respective line 12, 14 of the conductive channel.

The NMOS transistor [-->reference numeral MN1 in FIG. 4D] acts as an amplifier transistor or as a sink transistor to source or to sink the disturbance by current and to regulate the voltage near the switching unit 20.

The first embodiment of the circuit arrangement in the form of the analogue switch 100 according to the present invention as depicted in FIG. 4A to FIG. 4D has been designed and tested as a part of design of experiment. The simulation and testing verifies the desired goals. The simulation results are as follows:

An advantageous operating range for the first embodiment of the analogue switch 100 (cf. FIG. 4A to FIG. 4D) is a supply voltage Vcc between about 1.65 Volt and about 3.6 Volt. The simulation results described below derive from an embodiment of the circuit arrangement 100 in the disabled state or disabled mode. The circuit arrangement 100 was powered by a supply voltage Vcc of 3.6 Volt and disabled by setting the enabling voltage Ven to zero.

In FIG. 5A, a second embodiment of a circuit arrangement 100′ according to the present invention is depicted, in particular with regard to a simulation setup for the evaluation of current-injection effect control.

In the disabled state or disabled mode, the current is forced into one side of a switching unit 20′, in particular of an overvoltage switch, and the effect of this current is measured on the other side of the overvoltage switch 20′.

In the simulation setup as depicted in FIG. 5A,
current is forced into a first pin [-->reference numeral pin1] wherein said first pin is connected to a first conductive channel or line Y, and
the current coming out of a second pin [-->reference numeral pin2] is measured wherein said first pin is connected to a second conductive channel or line Z said line Z being connected to an external resistance Rext of four Kiloohm; the external voltage Vext is set at zero.

FIG. 5B depicts simulation results of the current-injection effect control according to FIG. 5A under different process conditions, namely slow, typical and fast, as well as under different temperature conditions, namely
at ˜40 degree Celsius [-->reference numeral (6) in FIG. 5B],
at 25 degree Celsius [-->reference numeral (1) in FIG. 5B], and
at 85 degree Celsius [-->reference numeral (2) in FIG. 5B].

The current forced into the first pin [-->reference numeral pin1] was varied from zero to three Milliampere. As depicted in FIG. 5B, the maximum current out of the second pin [-->reference numeral pin2] and into the external resistance Rext was observed to be 10.5 Nanoampere. The rest of the current goes into the current control circuit 52, 54.

With reference to FIG. 4A and to FIG. 5A, the current going into various subblocks is shown in FIG. 5C, where detailed simulation results for the current-injection effect control are depicted; more particularly, in FIG. 5C
the current between the state control circuit or dualovervoltage block 30′ and a first pin terminal of the switching unit 20′ is designated with reference numeral Ia in FIG. 5C;
the current between the source-sink circuit 52′ and a D terminal of the switching unit 20′ is designated with reference numeral Ib in FIG. 5C;
the current between the source-sink circuit 52′ and a pin terminal of the switching unit 20′ is designated with reference numeral Ic in FIG. 5C; and
the current between a switch_0 and an Y terminal of the switching unit 20′, in particular a terminal being assigned to line Y, is designated with reference numeral Id in FIG. 5C.

In FIG. 6A, a third embodiment of a circuit arrangement 100″ according to the present invention is depicted, in particular with regard to a simulation setup for the evaluation of the current-injection effect control for the overvoltage mode.

The simulation set up for the overvoltage protection is shown in FIG. 6A. This setup is similar to the setup of FIG. 5A except that line Y is driven by a voltage source instead of a current source.

The voltage on line Y is varied from about 3.2 Volt to about four Volt, and the current going into the first pin [-->reference numeral pin1] as well as the current coming out of the second pin [-->reference numeral pin2] is measured under different process conditions, namely slow, typical and fast, as well as under different temperature conditions.

In FIG. 6B, the simulation results for overvoltage leakage are depicted:

It can be taken from FIG. 6B that under no overvoltage, i.e. when the voltage of line Y is lower than a supply voltage Vcc of 3.6 Volt, there is no current into the first pin [-->reference numeral pin1] as well as into the second pin [-->reference numeral pin2]. The current into the first pin [-->reference numeral pin1] increases as voltage on line Y goes above the supply voltage Vcc. This current is sinked by the source-sink circuit 52′, 54′.

The maximum disturbance on line Z can be observed by measuring the current coming out of the second pin [-->reference numeral pin2] through the external resistance Rext of four Kiloohm.

The current deriving from a resistor R_1 being assigned to the second sink-source circuit 54′ is designated with reference numeral I(R_1) in FIG. 6B; the current being provided at the first pin terminal of the switching unit 20′ is designated with reference numeral I(20′pin1) in FIG. 6B.

The current out of the second pin [-->reference numeral pin2] can be seen to be in the range between about ten Nanoampere and about twenty Nanoampere. The current into the first pin [-->reference numeral pin1] can be seen to increase as voltage on line Y increases. The current into the first pin [-->reference numeral pin1] gets saturated depending on the current sinking capabilities of the source-sink circuit block 52′, 54′.

With reference to FIG. 4A and to FIG. 5A, the current going into various subblocks is shown in FIG. 6C, where detailed simulation results for the current-injection effect control are depicted.

The simulation results of the circuit arrangement 100′ (cf. FIG. 5B and FIG. 5C) and of the circuit arrangement 100″ (cf. FIG. 6B and FIG. 6C) shown above prove that the circuit arrangement according to the present invention can be used in applications where
features such as overvoltage and/or undervoltage and
current-injection effect control features
   are needed. The simulation above used for overvoltage and current sinking mode is shown but the similar analysis for undervoltage, i.e. line voltage under zero Volt and current sourcing mode can be done.

According to a preferred embodiment, the circuit arrangement 100, 100′, 100″, in particular the state control circuit 30, the bipolar control circuit 40, and the current control circuit 52, 54 can be completely static and can conduct current only when required. In this way, normal operation of the circuit arrangement 100, 100′, 100″, in particular of the analogue switch, is still maintained and the circuit arrangement 100, 100′, 100″ remains completely static.

Because of its static design, the circuit arrangement 100, 100′, 100″ can be used in low power applications. Also, it is designed using a general CMOS process; thus, the circuit arrangement 100, 100′, 100″ can be easily produced at very low price.

The circuit arrangement 100, 100′, 100″ according to the present invention leads to the advantage of eliminating the need for external resistance or diode network to keep the analog signal range within the range of the supply voltage Vcc. This feature is especially useful in automotive applications.

In conclusion, a preferred embodiment of the present invention can be implemented as a schematic of a compensated switch for allowing signals on the input line 12 of the conductive channel and on the output line 14 of the conductive channel (cf. FIG. 4A to FIG. 4D) or on the Y/Z pins (cf. FIG. 5A to FIG. 6C) to go beyond rail-to-rail values in the disabled state of the transistor means 20, 20′.

The main advantages of this design are as follows:
static design for low voltage advanced applications;
isolation of switch lines under fault conditions;
no need for external resistance or diode network, and
better leakage estimation, as parasitic bipolar modeling is not required.

Spice simulations under various process conditions as well as under various temperature conditions prove the concept. Simulation results are shown for overvoltage conditions (line voltage higher than supply voltage Vcc) but the analysis can easily be derived for for undervoltage signals (line voltage lower than ground potential gnd).

### LIST OF REFERENCE NUMERALS

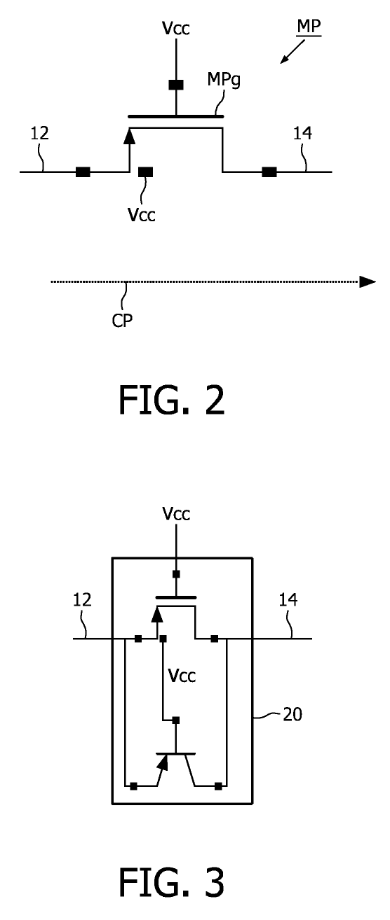

100 circuit arrangement, in particular switching device or multiplexing device and/or demultiplexing device, for example analog switch or analog multiplexer and/or analog demultiplexer (first embodiment; cf. FIG. 4A to FIG. 4D)
100′ circuit arrangement, in particular switching device, for example overvoltage switch (second embodiment; cf. FIG. 5A)
100″ circuit arrangement, in particular switching device, for example overvoltage switch (third embodiment; cf. FIG. 6A)
12 first part, in particular first rail, for example input line, of conductive channel
14 second part, in particular second rail, for example output line, of conductive channel
20 transistor means, in particular switching unit implemented as metal-oxide semiconductor (MOS), for example as complementary metal-oxide semiconductor (CMOS), such as complementary high-density metal-oxide semiconductor (CHMOS) and/or as bipolar complementary metal-oxide semiconductor (BiCMOS) (first embodiment; cf. FIG. 4A to FIG. 4D)
20′ transistor means, in particular switching unit implemented as metal-oxide semiconductor (MOS), for example overvoltage switch (second embodiment; cf. FIG. 5A; third embodiment; cf. FIG. 6A)
30 state control circuit, in particular dualovervoltage unit (first embodiment; cf. FIG. 4A and FIG. 4B)
30′ state control circuit, in particular dualovervoltage unit (second embodiment; cf. FIG. 5A; third embodiment; cf. FIG. 6A)
32 backflow-prevention circuit of state control circuit 30
34 signal level circuit, in particular maximum-finding block, of state control circuit
40 bipolar control circuit, in particular backgate-logic unit (first embodiment; cf. FIG. 4A and FIG. 4B)
42 backflow-prevention circuit of bipolar control circuit 40
44 backgate control circuit, in particular dynamic backgate control block, of bipolar control circuit 40
52 first source-sink circuit of current control circuit (first embodiment; cf. FIG. 4A and FIG. 4D)
52′ first source-sink circuit of current control circuit (second embodiment; cf. FIG. 5A)
52″ first source-sink circuit of current control circuit (third embodiment; cf. FIG. 6A)
54 second source-sink circuit of current control circuit (first embodiment; cf. FIG. 4A and FIG. 4D)
54′ second source-sink circuit of current control circuit (second embodiment; cf. FIG. 5A; third embodiment; cf. FIG. 6A)
bg backgate of transistor means 20, in particular backgate of p-type transistor unit MP or backgate of n-type transistor unit MN
CP current path due to M[etal-]O[xide]S[emiconductor] effect, in particular due to C[omplementary]M[etal-]O[xide]S[emiconductor] effect (cf. FIG. 2)
En enable signal or enabling signal
gnd ground level or ground potential or grounding
Ia current between state control circuit 30′ and terminal of first pin pin1 of switching unit 20′ (second embodiment; cf. FIG. 5C; third embodiment; cf. FIG. 6C)
Ib current between source-sink circuit 52′, 52″ and D terminal of switching unit 20′ (second embodiment; cf. FIG. 5C; third embodiment; cf. FIG. 6C)
Ic current between source-sink circuit 52′, 52″ and pin terminal of switching unit 20′ (second embodiment; cf. FIG. 5C; third embodiment; cf. FIG. 6C)
Id current between switch_0 and Y terminal of switching unit 20′ (second embodiment; cf. FIG. 5C; third embodiment; cf. FIG. 6C)
Inv_0 inverter unit
pin1 first pin, in particular pin of first part of conductive channel 12
pin2 second pin, in particular pin of second part conductive channel 14
MN n-type transistor unit, in particular n-channel metal-oxide semiconductor (NMOS) or n-type metal-oxide semiconductor field effect transistor (NMOSFET), of transistor means 20
MP p-type transistor unit, in particular p-channel metal-oxide semiconductor (PMOS) or p-type metal-oxide semiconductor field effect transistor (PMOSFET), of transistor means 20
MPg gate of p-type transistor unit MP (cf. FIG. 2)
Vcc supply voltage being provided by power supply, in particular connected to collector terminal of transistor means 20
Y line connected with first pin pin1 (second embodiment; cf. FIG. 5A; third embodiment; cf. FIG. 6A)
Z line connected with second pin pin2 (second embodiment; cf. FIG. 5A; third embodiment; cf. FIG. 6A)

1. A circuit arrangement comprising
at least one conductive channel being designed for transmitting at least one analog and/or digital signal from at least one first pin to at least one second pin and
at least one transistor means
being connected between the first pin and the second pin via the conductive channel and
being switchable between at least one enabled state and at least one disabled state in dependence on the signal level of at least one voltage and/or current signal,
characterized by
at least one state control circuit for preventing the transistor means from starting to conduct due to being provided with at least one unwanted signal in its disabled state, and
at least one current control circuit for preventing that at least one unwanted current peak is transmitted from at least one first part of the conductive channel to at least one second part of the conductive channel, with the transistor means being arranged between said first part and said second part.

2. The circuit arrangement according to claim 1, characterized in that the transistor means comprises
at least one p-type transistor unit, in particular at least one p-channel metal-oxide semiconductor (PMOS) or p-type metal-oxide semiconductor field effect transistor (PMOSFET), starting to conduct in case of application of a higher voltage on its drain electrode and/or on it source electrode than on its gate electrode, and/or
at least one n-type transistor unit (MN), in particular at least one n-channel metal-oxide semiconductor (NMOS) or n-type metal-oxide semiconductor field effect transistor (NMOSFET), starting to conduct in case of application of a lower voltage on its drain electrode and/or on it source electrode than on its gate electrode,
wherein the transistor means can be implemented as at least one metal-oxide semiconductor (MOS), in particularly as at least one complementary metal-oxide semiconductor (CMOS), for example as at least one complementary high-density metal-oxide semiconductor (CHMOS) and/or as at least one bipolar complementary metal-oxide semiconductor (BiCMOS).

3. The circuit arrangement according to claim 1, characterized in that the state control circuit comprises
at least one backflow-prevention circuit being designed for preventing the unwanted signal from being transmitted to at least one power supply (Vcc) of the circuit arrangement and/or
at least one signal level circuit
comprising at least one detector means for detecting the unwanted signal, in particular for detecting overvoltage and/or for detecting undervoltage, and
being designed for controlling the signal level of at least one electrode of the transistor means, in particular
for rising the signal level of the gate electrode of the p-type transistor unit (MP) in case of overvoltage and/or
for lowering the signal level of the gate electrode of the n-type transistor unit (MN) in case of undervoltage.

4. The circuit arrangement according to claim 1, characterized in that the current control circuit comprises
at least one first source-sink circuit
being arranged between the first pin and the transistor means and
being designed for eliminating the unwanted current peak being provided by at least one impedance source, in particular by at least one current source, being connected to the first part of the conductive channel, and
at least one second source-sink circuit
being arranged between the transistor means and the second pin and
being designed for eliminating the unwanted current peak being provided by at least one impedance source, in particular by at least one current source, being connected to the second part of the conductive channel.

5. The circuit arrangement according to claim 1, characterized by at least one bipolar control circuit for protecting the transistor means against at least one parasitic bipolar effect, in particular for preventing the transistor means signal leakage due to said parasitic bipolar effect, the bipolar control circuit in particular comprising
at least one backflow-prevention circuit for preventing at least one current from being injected into at least one backgate (bg) of the transistor means, in particular from being injected into at least one parasitic bipolar transistor (PNP) being formed by at least one source-drain-backgate of the transistor, for example by at least one emitter-collector-base of the transistor means, and/or
at least one backgate control circuit for controlling, in particular for dynamically controlling, the voltage level of the backgate (bg) of the transistor means, in particular for rising and/or for lowering the voltage level of said backgate (bg) of the transistor means, in dependence on the voltage level of the first pin and/or of the second pin (pin2) and/or of the power supply (Vcc).

6. A method for controlling and/or for preventing injection current, said method comprising
switching at least one transistor means between at least one enabled state and at least one disabled state in dependence on the signal level of at least one voltage and/or current signal, and
transmitting at least one analog and/or digital signal from at least one first pin to at least one second pin via at least one conductive channel in the enabled state of the transistor means,
characterized by
preventing the transistor means from starting to conduct due to being provided with at least one unwanted signal in its disabled state, and
preventing transmission of at least one unwanted current peak from at least one first part of the conductive channel to at least one second part of the conductive channel, with the transistor means being arranged between said first part and said second part.

7. The method according to claim 6, characterized in that said preventing the transistor means from starting to conduct comprises
detecting the unwanted signal, in particular detecting overvoltage or undervoltage, and
controlling the signal level of at least one electrode of the transistor means, in particular
rising the signal level of the gate electrode of at least one p-type transistor unit (MP) of the transistor means case of overvoltage, in particular said p-type transistor unit (MP) starting to conduct in case of at least one negative voltage being placed on its gate electrode, and/or
lowering the signal level of the gate electrode of at least one n-type transistor unit (MN) of the transistor means in case of undervoltage, in particular said n-type transistor unit (MN) starting to conduct in case of at least one positive voltage being placed on its gate electrode.

8. The method according to claim 6, characterized in that said preventing of the transmission of the unwanted current peak comprises
sensing, in particular dynamic sensing, of the unwanted current peak and
providing at least one low impedance path for the current peak to the power supply (Vcc) and/or to the grounding (gnd).

9. The method according claim 6, characterized by protecting the transistor means against at least one parasitic bipolar effect, in particular preventing the transistor means from signal leakage due to said parasitic bipolar effect, said protecting of the transistor means against said parasitic bipolar effect in particular comprising
controlling, in particular dynamically controlling, the voltage level of at least one backgate (bg) of the transistor means, in particular rising and/or lowering the voltage level of said backgate (bg) of the transistor means in dependence on the voltage level of the first pin and/or of the second pin and/or of the power supply (Vcc), and/or
preventing at least one current from being injected into the backgate (bg) of the transistor means, in particular from being injected into at least one parasitic bipolar transistor (PNP) being formed by at least one source-drain-backgate of the transistor means for example by at least one emitter-collector-base of the transistor means.

10. Use of at least one circuit arrangement according to claim 1 and/or of a method according to claim 6
for at least one application, in particular for at least one automotive application, where overvoltage, for example voltage in excess of normal supply voltage, may appear and/or
in at least one A[nalog]/D[igital] converter, in at least one bus interface, in at least one data acquisition system, in at least one level shifter, and/or in at least one personal computer,
wherein the circuit arrangement can be implemented as at least one switching device, in particular as at least one analog switch, and/or as at least one multiplexing device and/or as at least one demultiplexing device, for example as at least one analog multiplexer and/or as at least one analog demultiplexer.
